(19) United States
(12) Patent Application Publication
(10) Pub. No.: US 2024/0305026 A1
(43) Pub. Date: Sep. 12, 2024

(54) CONNECTOR ASSEMBLY WITH INTEGRATED DATA AND BACKUP ENERGY CONNECTIONS

(71) Applicant: Micron Technology, Inc., Boise, ID (US)

(72) Inventors: Mark A. Tverdy, Boise, ID (US); Kaleb A. Wilson, Caldwell, ID (US)

(21) Appl. No.: 18/596,264

(22) Filed: Mar. 5, 2024

Related U.S. Application Data
(60) Provisional application No. 63/451,126, filed on Mar. 9, 2023.

(51) Int. Cl. H01R 12/73; H01R 12/70; H01R 25/00; H05K 7/02; H05K 7/10

(52) U.S. Cl. CPC H01R 12/73; H01R 12/7088; H01R 25/006; H05K 7/023; H05K 7/1076

(57) ABSTRACT

Various embodiments described herein provide a connector assembly with integrated data and backup energy connections, which can be used to electrically couple together two or more printed circuit boards and electrically couple at least one of those printed circuit boards to a backup energy source. For example, a connector assembly of an embodiment can be used to implement a memory sub-system by coupling together two or more printed circuit boards of the memory sub-system and coupling the memory sub-system to a backup energy source, such as a set of capacitors or a set of batteries, which can be used to power the memory sub-system in the event of a main power loss.

### PRIORITY APPLICATION

This application claims the benefit of priority to U.S. Provisional Application Ser. No. 63/451,126, filed Mar. 9, 2023, which is incorporated herein by reference in its entirety.

### TECHNICAL FIELD

Embodiments of the disclosure relate generally to connectors for circuits and, more specifically, to a connector assembly with integrated data and backup energy connections, which can be used to electrically couple together two or more printed circuit boards and electrically couple at least one of those printed circuit boards to a backup energy source.

### BACKGROUND

A memory sub-system can be a storage device, a memory module, or a hybrid of a storage device and memory module. Certain memory sub-systems comprise two or more circuit components, such as printed circuit boards (PCBs), that are physically and electrically coupled together within a housing assembly. Conventional methodologies for connecting two or more circuit boards, especially circuit boards that are stacked (e.g., vertically or horizontally) next to each other, includes rigid PCBs (e.g., with edge card connectors disposed thereon), or flex or semi-flex PCBs (e.g., rigid-flex-rigid (RFR) PCB).

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example of a connector assembly, in accordance with some embodiments of the present disclosure.

FIG. 2 illustrates a cross section view of a connector assembly, in accordance with some embodiments of the present disclosure.

FIGS. 3 and 4 illustrate memory sub-systems that comprise a connector assembly, in accordance with some embodiments of the present disclosure.

FIG. 5 illustrates insertion of printed circuit boards into a connector assembly, in accordance with some embodiments of the present disclosure.

FIG. 6 illustrates insertion of printed circuit boards into a connector assembly and a backup energy source connected to the connector assembly, in accordance with some embodiments of the present disclosure.

FIG. 7 is a block diagram illustrating how a connector assembly can be used to implement a memory sub-system within an example computing environment, in accordance with some embodiments of the present disclosure.

### DETAILED DESCRIPTION

Aspects of the present disclosure are directed to a connector assembly with integrated data and backup energy connections, which can be used to electrically couple together two or more printed circuit boards and electrically couple at least one of those printed circuit boards to a backup energy source. For example, a connector assembly of an embodiment can be used to implement a memory sub-system by coupling together two or more printed circuit boards of the memory sub-system and coupling the memory sub-system to a backup energy source, such as a set of capacitors or a set of batteries, which can be used to power the memory sub-system in the event of a main power loss.

According to some embodiments, the connector assembly comprises a first slot configured to receive a first edge of a first printed circuit board (PCB), a second slot configured to receive a second edge of a second PCB, and a set of electrical connectors configured to be electrically coupled to a backup energy source. For some embodiments, the first slot comprises a first plurality of electrically-conductive biased contacts (e.g., biased contacts) configured to electrically couple with corresponding electrically-conductive surface contacts disposed (e.g., mounted) on the first edge of the first PCB after the first edge is received by and inserted into the first slot, and the second slot comprises a second plurality of electrically-conductive biased contacts configured to electrically couple with corresponding electrically-conductive surface contacts disposed (e.g., mounted) on the second edge of the second PCB after the second edge is received by and inserted into the second slot. For some embodiments, a first set of electrically-conductive biased contacts of the first plurality is electrically coupled to a second set of electrically-conductive biased contacts of the second plurality. In doing so, some embodiments facilitate a board-to-board connection (e.g., data connection) between the first and the second PCBs. For some embodiments, a third set of electrically-conductive biased contacts of the first plurality is electrically coupled to the set of electrical connectors. In doing so, some embodiments permit a backup energy source to provide power (e.g., voltage) to the first PCB through the connection assembly in the event that a primary energy source (e.g., main power supply) to the first PCB fails to (or can no longer) provide energy (e.g., power) to the first PCB. Additionally, for some embodiments, a fourth set of electrically-conductive biased contacts of the second plurality is electrically coupled to the set of electrical connectors, which can permit the backup energy source to provide power (e.g., voltage) to the second PCB through the connection assembly in the event that a primary energy source (e.g., main power supply) to the second PCB fails to provide energy (e.g., power) to the second PCB.

Various embodiments described herein can be used in a number of different applications or environments where a board-to-board connection is needed and a backup energy source is involved. For instance, the connector assembly can be used where a first printed circuit board and a second printed circuit board implement a memory sub-system. The first printed circuit board can comprise a separate connector configured to electrically couple to, and receive main power from, a host system, where the separate connector is separate from the conductive surface contacts disposed on the first edge of the first printed circuit board. In the event of a main power loss (e.g., from a main energy source), the first printed circuit board can be configured to receive backup power from the third set of electrically-conductive biased contacts by way of the third set of electrically-conductive biased contacts of the first plurality.

With respect to electrically-conductive contacts, for some embodiments, the first plurality of electrically-conductive biased contacts is disposed on at least one side of the first slot, and the second plurality of electrically-conductive biased contacts is disposed on at least one side of the second slot. Depending on the embodiment, the first slot can be a first edge board connector, and the second slot can be a second edge board connector. Each biased contact of the first plurality of electrically-conductive biased contacts can be part of a horseshoe shaped element (e.g., horseshoe shaped metal piece), and each biased contact of the second plurality of electrically-conductive biased contacts can be part of a horseshoe shaped (e.g., horseshoe shaped metal piece). In various embodiments, the connector assembly is constructed from plastic, and each biased contact of the first plurality of electrically-conductive biased contacts can be over-molded in the plastic, or each biased contact of the second plurality of electrically-conductive biased contacts can be over-molded in the plastic.

For some embodiments, the set of electrical connectors of the connector assembly are lugs (e.g., two lugs) configured to electrically connect to a positive terminal of a backup energy source and a negative terminal of the backup energy source. Additionally, for some embodiments, the connector assembly comprises a set of pins accessibly outside of the connector assembly, where the set of pins is configured to provide debug access to (and to electrically couple to) at least one of the first printed circuit board or the second printed circuit board.

According to some embodiments, the first printed circuit board is manufactured using a surface-mount technology (SMT) process. For some embodiments, the first edge of the first printed circuit board functions as an edge connector, and the second edge of the second printed circuit board functions as another edge connector.

For some embodiments, the first slot and the second slot are positioned parallel and adjacent to each other (e.g., parallel in a spaced relationship) in a housing of the connector assembly. For instance, the first slot and the second slot can be positioned such that the first printed circuit board and the second circuit board are stacked in parallel and next to each other (e.g., parallel in a spaced relationship) after the first printed circuit board is inserted into the first slot and the second printed circuit board is inserted into the second slot. In doing so, depending on the orientation of the connector assembly within an apparatus (e.g., device), the first printed circuit board and the second printed circuit board can be stacked horizontally or vertically next to each other.

With respect to a housing of a connector assembly, the connector assembly can comprise a main housing that comprises (e.g., contains or houses) the first slot and the second slot, and an extended housing that extends away from the main housing and that comprises (e.g., contains or houses) the set of electrical connectors for the backup energy source (e.g., separate from the first slot and the second slot). For some embodiments, the set of electrical connectors can be electrically coupled to the third set of electrically-conductive biased contacts of the first plurality by an electrically-conductive path (e.g., metal wire or metal trace) contained within the extended housing and the main housing.

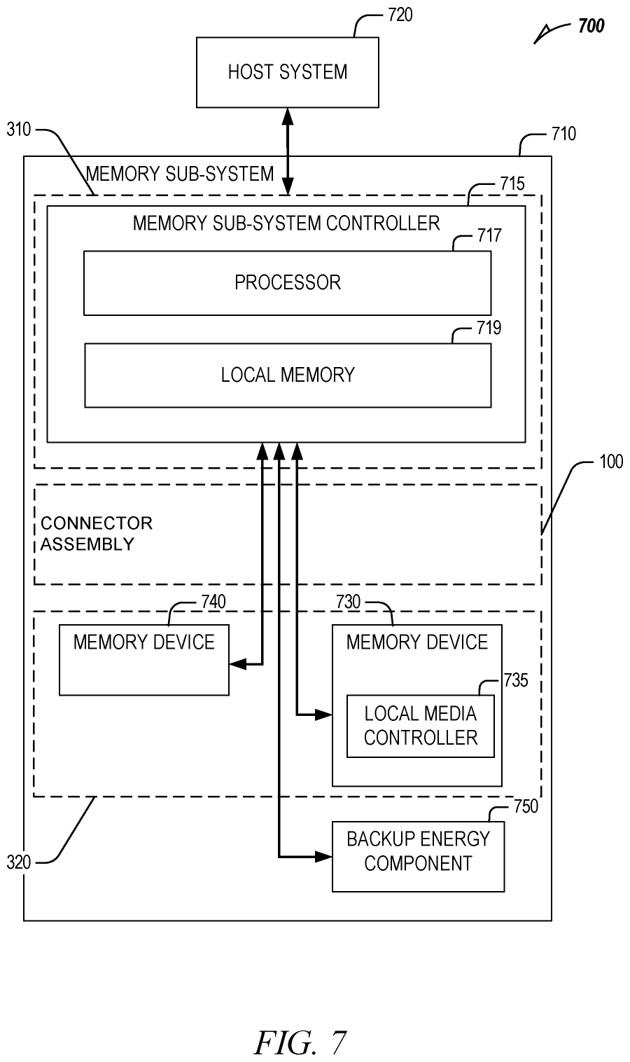

As used herein, a biased contact can comprise a biased contact. A memory sub-system can be a storage device, a memory module, or a hybrid of a storage device and memory module. Examples of storage devices and memory modules are described below in conjunction with FIG. 7. In general, a host system can utilize a memory sub-system that includes one or more memory components (also hereinafter referred to as “memory devices”). The host system can provide data to be stored at the memory sub-system and can request data to be retrieved from the memory sub-system. As used herein, a backup energy source (e.g., of a memory sub-system) can include any form of energy source that can provide power when there is a loss of power from a main power energy source. Examples of backup energy sources can include a set of batteries or a set of capacitors.

Though various embodiments are described herein with respect to two printed circuit boards (PCBs), a connector assembly of some embodiments can be used with three or more PCBs and provide features similar to those described herein.

Disclosed herein are some examples of connector assemblies with integrated data and backup energy connections, which can be used in implementing a memory sub-system.

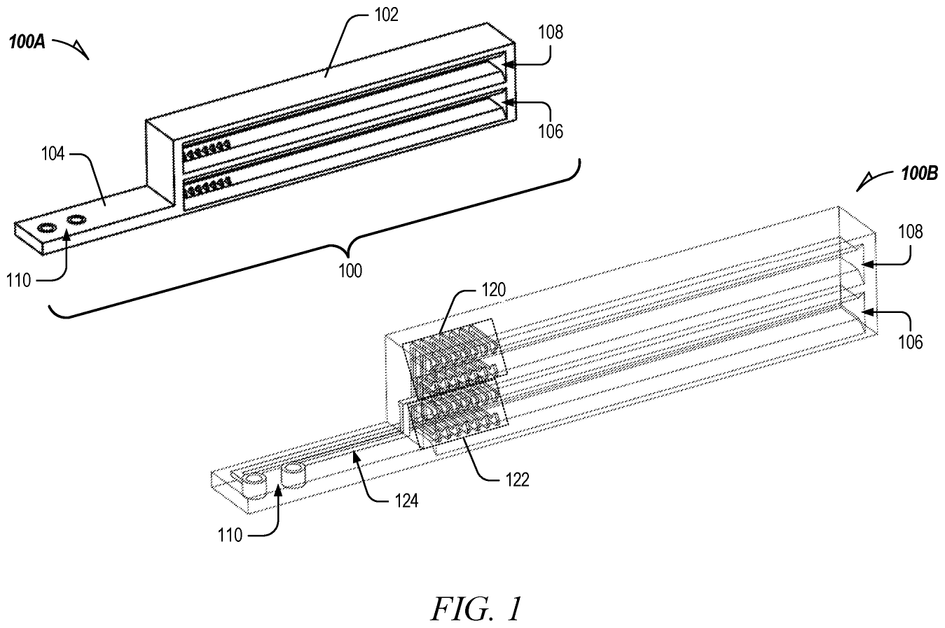

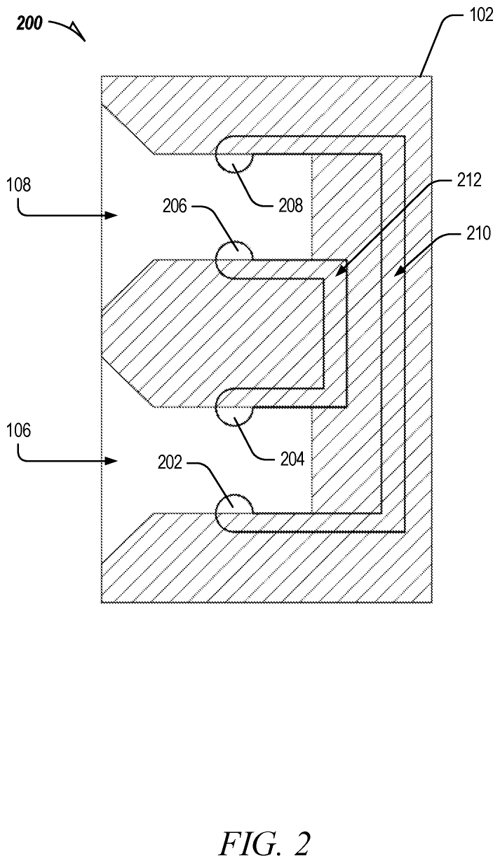

FIG. 1 illustrates an example of a connector assembly, in accordance with some embodiments of the present disclosure. In particular, view 100A presents a perspective view of the connector assembly (hereafter referred to as “connector assembly 100”), and view 100B presents an exposed view of the connector assembly. In FIG. 1, the connector assembly 100 comprises a main housing 102 and an extended housing 104 that extends away from the main housing 102. As shown, the main housing 102 comprises a first slot 106 that is configured to receive and connect to a first edge of a first printed circuit board, and a second slot 108 that is configured to receive and connect to a second edge of a second printed circuit board. As shown in view 100B, the first slot 106 comprises a first plurality of electrically-conductive biased contacts 122 configured to electrically couple with corresponding electrically-conductive surface contacts (e.g., contact pads), disposed on the first edge of the first printed circuit board, after the first edge is received by and inserted into the first slot. Similarly, the second slot 108 comprises a second plurality of electrically-conductive biased contacts 120 configured to electrically couple with corresponding electrically-conductive surface contacts (e.g., contact pads), disposed on the second edge of the second printed circuit board, after the second edge is received by and inserted into the second slot. For each of the first slot 106 and the second slot 108, the biased contacts are disposed on (e.g., line) each side wall of the slot. For some embodiments, a first set of the first plurality of electrically-conductive biased contacts 122 is electrically coupled to a second set of the second plurality of electrically-conductive biased contacts 120, thereby facilitating board-to-board connection between the first and the second printed circuited boards after the boards are respectively received by and inserted into the first slot 106 and the second slot 108. Depending on the embodiment, the board-to-board connection through the connector assembly 100 can include data connections and power connections (e.g., where the first printed circuit board receives main power from a main energy source, and provides or shares that main power with the second printed circuit board via the connector assembly 100). A given biased contact of the first plurality of electrically-conductive biased contacts 122 can be part of a horseshoe-shaped element (e.g., horseshoe-shaped metal piece) that extends from the first slot 106 to a given biased contact of the second plurality of electrically-conductive biased contacts 120 of the second slot 108. An example of hits is illustrated and described with respect to FIG. 2.

The extended housing 104 comprises electrical connectors 110, which can connect to an energy source, such as a backup energy source (e.g., a set of batteries or a set of capacitors). As shown in view 100B, the electrical connectors 110 can comprise lugs that can connect to positive and negative terminals of an energy source. As also shown in view 100B, a set of the first plurality of electrically-conductive biased contacts 122 and a set of the second plurality of electrically-conductive biased contacts 120 are each electrically coupled to the electrical connectors 110 by way of a conductive path 124, thereby permitting a backup energy source that is connected to the electrical connectors 110 to provide backup power to each of the first printed circuit board inserted into the first slot 106 and the second printed circuit board inserted into the second slot 108.

FIG. 2 illustrates a cross-sectional view 200 of the connector assembly 100, in accordance with some embodiments of the present disclosure. In particular, the cross-sectional view 200 presents a cross section of the main housing 102 of the connector assembly 100. As shown, the first slot 106 (of the main housing 102) comprises a biased contact 202 disposed on one side wall of the first slot 106 and a biased contact 204 disposed on another side wall of the first slot 106, and the second slot 108 (of the main housing 102) comprises a biased contact 206 disposed on one side wall of the second slot 108 and a biased contact 208 disposed on another side wall of the second slot 108. As also shown, the biased contacts 202, 208 are part of a horseshoe-shaped metal element 210, and the biased contacts 204, 206 are part of a horseshoe-shaped metal element 212.

After a first printed circuit board is inserted into the first slot 106, a first surface contact disposed on a side of the edge of the first printed circuit board (the side facing the biased contact 202) comes in contact with the biased contact 202, thereby electrically coupling the first surface contact with the biased contact 202. After a second printed circuit board is inserted into the second slot 108, a second surface contact disposed on a side of the edge of the second printed circuit board (the side facing the biased contact 208) comes in contact with the biased contact 208, thereby electrically coupling the second surface contact with the biased contact 208. By way of the horseshoe-shaped metal element 210 and the biased contacts 202 and 208, the connector assembly 100 can electrically couple the first surface contact of the first printed circuit board with the second surface contact of the second printed circuit board.

Similarly, after the first printed circuit board is inserted into the first slot 106, a third surface contact disposed on the other side of the edge of the first printed circuit board (the side facing the biased contact 204) comes in contact with the biased contact 204, thereby electrically coupling the third surface contact with the biased contact 204. After the second printed circuit board is inserted into the second slot 108, a fourth surface contact disposed on the other side of the edge of the second printed circuit board (the side facing the biased contact 206) comes in contact with the biased contact 206, thereby electrically coupling the fourth surface contact with the biased contact 206. By way of the horseshoe-shaped metal element 212 and the biased contacts 204 and 206, the connector assembly 100 can electrically couple the third surface contact of the first printed circuit board with the fourth surface contact of the second printed circuit board.

The main housing 102 of the connector assembly 100 can comprise additional “inner” horseshoe-shaped metal elements (like the horseshoe-shaped metal element 212) and “outer” horseshoe-shaped metal elements (like the horseshoe-shaped metal element 210) that correspond to other surface contacts disposed on the edges of the first and the second printed circuited boards and that electrically couple those surface contacts in a similar manner.

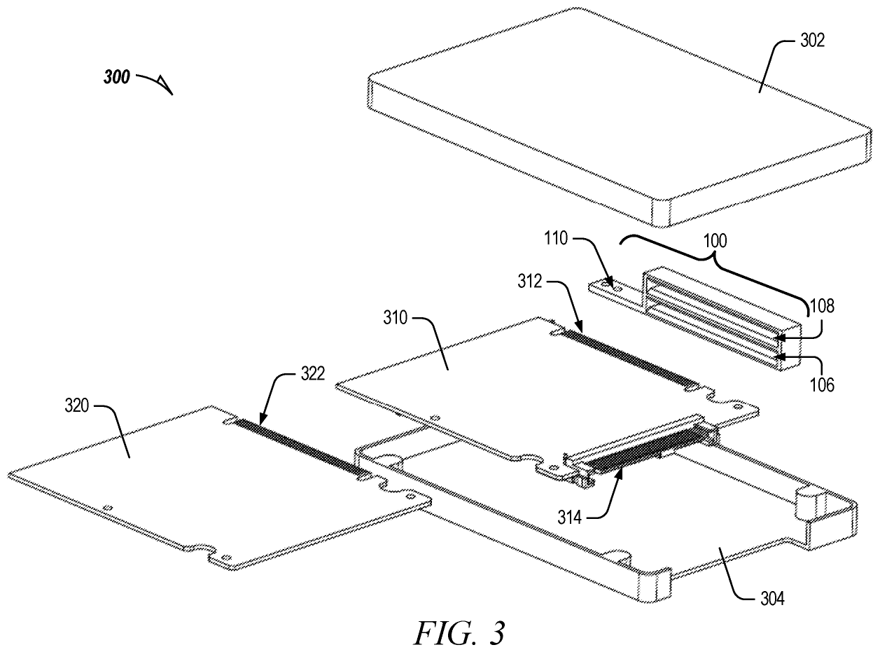

FIG. 3 illustrates an exploded view of a memory sub-system 300 that comprises the connector assembly 100, in accordance with some embodiments of the present disclosure. In FIG. 3, the memory sub-system 300 has an exterior housing comprising an upper portion 302 and a lower portion 304. The memory sub-system 300 comprises a first printed circuit board 310 comprising an edge 312, and a second printed circuit board 320 comprising an edge 322. The edge 312 can comprise one or more surface contacts disposed on the edge 312 (e.g., one side or both sides), and the edge 322 one or more surface contacts disposed on the edge 322 (e.g., one side or both sides). Additionally, the first printed circuit board 310 comprises a host connector 314 configured to electrically couple the first printed circuit board (e.g., and the memory sub-system 300) to a host system. For some embodiments, the first printed circuit board 310 comprises at least one of a memory sub-system controller, and power circuitry (e.g., to enable powering of the memory sub-system 300 by main power provided the host connector 314). Additionally, for some embodiments, the second printed circuit board 320 comprises a set of memory devices (e.g., one or more negative-and (NAND)-type memory devices). When the memory sub-system 300 is assembled, the edge 312 of the first printed circuit board 310 can be inserted into the first slot 106 of the connector assembly 100, and the edge 322 of the second printed circuit board 320 can be inserted into the second slot 108 of the connector assembly 100. After the first printed circuit board 310 and the second printed circuit board 320 are inserted into the connector assembly 100, the resulting assembly can be placed within the exterior housing of the memory sub-system 300.

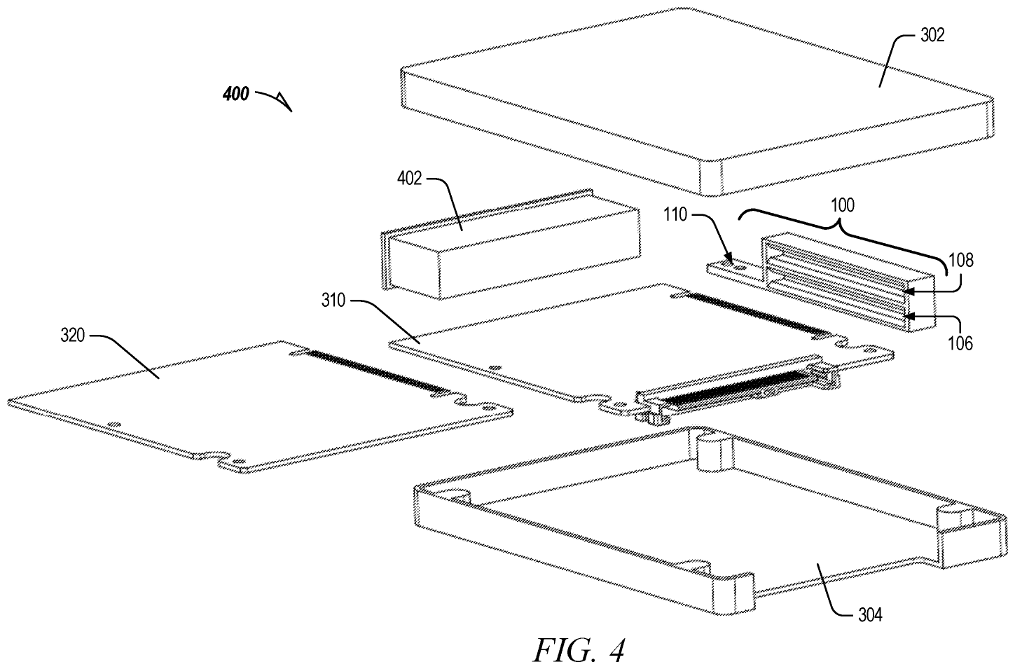

For some embodiments, the connector assembly 100 is configured to electrically couple together the first printed circuit board 310 and the second printed circuit board 320. Further, for some embodiments, the connector assembly 100 is configured to electrically couple the first printed circuit board 310, the second printed circuit board 320, or both to a backup energy source connected to the electrical connectors 110 of the connector assembly 100. For example, FIG. 4 illustrates an exploded view of a memory sub-system 400 that is similar to the memory sub-system 300 of FIG. 3 but includes a backup energy source 402, which can be connected to the electrical connectors 110. Depending on the embodiment, the backup energy source 402 can comprise a set of batteries or a set of capacitors, which can be configured to provide backup power to the memory sub-system 400 (e.g., backup power to the first printed circuit board 310) by way of the connector assembly 100.

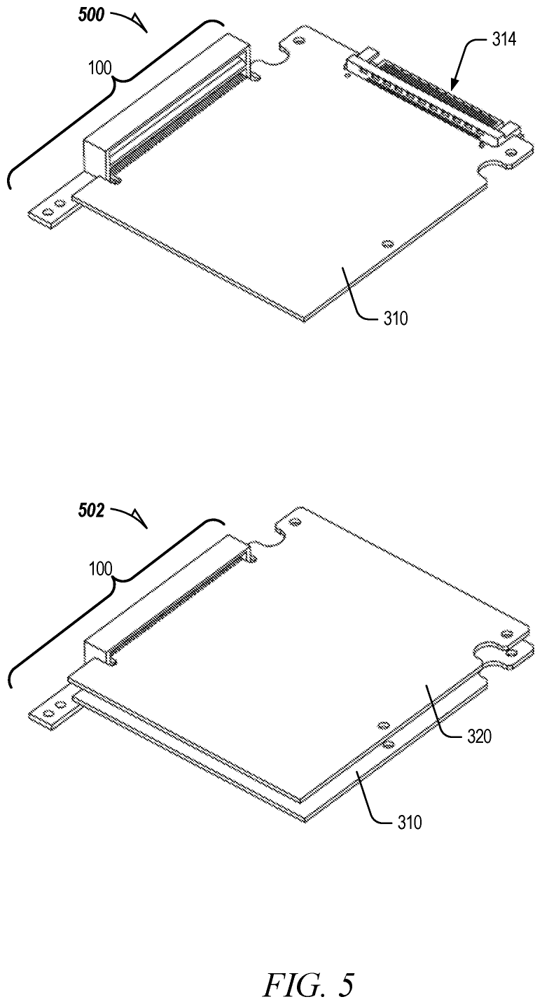

FIG. 5 illustrates insertion of the first printed circuit board 310 and the second printed circuit board 320 into the connector assembly 100, in accordance with some embodiments of the present disclosure. In particular, view 500 illustrates the connector assembly 100 after insertion of the first printed circuit board 310, and view 502 illustrates the connector assembly 100 after insertion of the first printed circuit board 310 and the second printed circuit board 320.

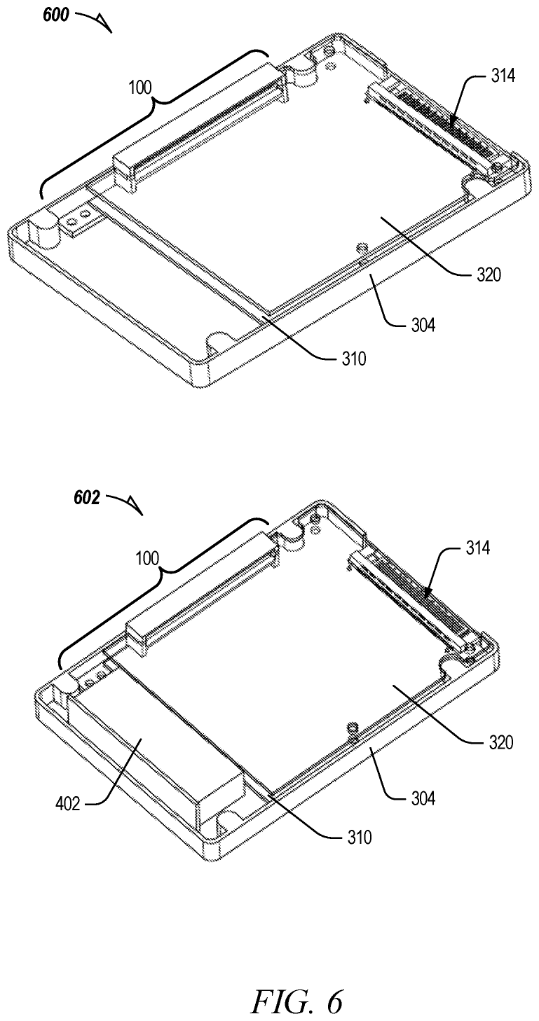

FIG. 6 illustrates insertion of the first printed circuit board 310 and the second printed circuit board 320 into the connector assembly 100, and connection of the backup energy source 402 to the connector assembly 100, in accordance with some embodiments of the present disclosure. In particular, view 600 illustrates the first printed circuit board 310, the second printed circuit board 320, and the connector assembly 100 placed in the lower portion 304 of the exterior housing of the memory sub-system 300. Additionally, view 602 shows the same but after the backup energy source 402 is placed in the lower portion 304 of the exterior housing of the memory sub-system 300.

FIG. 7 is a block diagram illustrating how the connector assembly 100 can be used to implement a memory sub-system 710 within an example computing environment 700, in accordance with some embodiments of the present disclosure. The memory sub-system 710 can include media, such as one or more volatile memory devices (e.g., memory device 740), one or more non-volatile memory devices (e.g., memory device 730), or a combination of such.

A memory sub-system 710 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 700 can include a host system 720 that is coupled to one or more memory sub-systems 710. In some embodiments, the host system 720 is coupled to different types of memory sub-system 710. FIG. 7 illustrates one example of a host system 720 coupled to one memory sub-system 710. The host system 720 uses the memory sub-system 710, for example, to write data to the memory sub-system 710 and read data from the memory sub-system 710. As used herein, “coupled to” generally refers to a connection between components, which can be an indirect communicative connection or direct communicative connection (e.g., without intervening components), whether wired or wireless, including connections such as electrical, optical, magnetic, etc.

The host system 720 can be a computing device such as a desktop computer, laptop computer, network server, mobile device, embedded computer (e.g., one included in a vehicle, industrial equipment, or a networked commercial device), or such computing device that includes a memory and a processing device. The host system 720 can be coupled to the memory sub-system 710 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 720 and the memory sub-system 710. The host system 720 can further utilize an NVM Express (NVMe) interface to access the memory components (e.g., memory devices 730) when the memory sub-system 710 is coupled with the host system 720 by the PCIe interface. The physical host interface can provide an interface for passing control, address, data, and other signals between the memory sub-system 710 and the host system 720.

The memory devices can include any combination of the different types of non-volatile memory devices and/or volatile memory devices. The volatile memory devices (e.g., memory device 740) can be, but are not limited to, random access memory (RAM), such as dynamic random-access memory (DRAM) and synchronous dynamic random-access memory (SDRAM).

An example of non-volatile memory devices (e.g., memory device 730) includes a negative-and (NAND) type flash memory. Each of the memory devices 730 can include one or more arrays of memory cells such as single-level cells (SLCs) or multi-level cells (MLCs) (e.g., triple-level cells (TLCs) or quad-level cells (QLCs)). In some embodiments, a particular memory component can include an SLC portion, and an MLC portion, a TLC portion, or a QLC portion of memory cells. Each of the memory cells can store one or more bits of data used by the host system 720. Furthermore, the memory cells of the memory devices 730 can be grouped as memory pages or memory blocks that can refer to a unit of the memory component used to store data.

Although non-volatile memory components such as NAND type flash memory are described, the memory device 730 can be based on any other type of non-volatile memory, such as read-only memory (ROM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 715 can communicate with the memory devices 730 to perform operations such as reading data, writing data, or erasing data at the memory devices 730 and other such operations. The memory sub-system controller 715 can include hardware such as one or more integrated circuits and/or discrete components, a buffer memory, or a combination thereof. The memory sub-system controller 715 can be a microcontroller, special purpose logic circuitry (e.g., a field programmable gate array (FPGA), an application specific integrated circuit (ASIC), etc.), or other suitable processor.

The memory sub-system controller 715 can include a processor (processing device) 717 configured to execute instructions stored in local memory 719. In the illustrated example, the local memory 719 of the memory sub-system controller 715 includes an embedded memory configured to store instructions for performing various processes, operations, logic flows, and routines that control operation of the memory sub-system 710, including handling communications between the memory sub-system 710 and the host system 720.

In some embodiments, the local memory 719 can include memory registers storing memory pointers, fetched data, etc. The local memory 719 can also include read-only memory (ROM) for storing micro-code. While the example memory sub-system 710 in FIG. 7 has been illustrated as including the memory sub-system controller 715, in another embodiment of the present disclosure, a memory sub-system 710 may not include a memory sub-system controller 715, and may instead rely upon external control (e.g., provided by an external host, or by a processor or controller separate from the memory sub-system).

In general, the memory sub-system controller 715 can receive commands or operations from the host system 720 and can convert the commands or operations into instructions or appropriate commands to achieve the desired access to the memory devices 730. The memory sub-system controller 715 can be responsible for other operations such as wear leveling operations, garbage collection operations, error detection and error-correcting code (ECC) operations, encryption operations, caching operations, and address translations between a logical block address and a physical block address that are associated with the memory devices 730. The memory sub-system controller 715 can further include host interface circuitry to communicate with the host system 720 via the physical host interface. The host interface circuitry can convert the commands received from the host system into command instructions to access the memory devices 730 as well as convert responses associated with the memory devices 730 into information for the host system 720.

The memory sub-system 710 can also include additional circuitry or components that are not illustrated. In some embodiments, the memory sub-system 710 can include a cache or buffer (e.g., DRAM) and address circuitry (e.g., a row decoder and a column decoder) that can receive an address from the memory sub-system controller 715 and decode the address to access the memory devices 730.

In some embodiments, the memory devices 730 include local media controllers 735 that operate in conjunction with memory sub-system controller 715 to execute operations on one or more memory cells of the memory devices 730.

As shown, the memory sub-system 710 includes a backup energy component 750 that can represent a backup energy source (e.g., the backup energy source 402), such as a set of batteries or a set of capacitors (e.g., power backup capacitor banks). The backup energy component 750 can provide various components of the memory sub-system 710 with backup power in the event of primary power loss to the memory sub-system 710. As shown, according to some embodiments, the first printed circuit board 310 comprises the memory sub-system controller 715, the second printed circuit board 320 comprises the memory devices 730, 740, and the connector assembly 100 electrically-couples together the first printed circuit board 310 and the second printed circuit board 320, and electrically-couples the backup energy component 750 to the first printed circuit board 310.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A connector assembly comprising:
a main housing comprising:
a first slot configured to receive a first edge of a first printed circuit board, the first slot comprising a first plurality of electrically-conductive biased contacts configured to electrically couple with corresponding electrically-conductive surface contacts disposed on the first edge; and
a second slot configured to receive a second edge of a second printed circuit board, the second slot comprising a second plurality of electrically-conductive biased contacts configured to electrically couple with corresponding electrically-conductive surface contacts disposed on the second edge, a first set of electrically-conductive biased contacts of the first plurality being electrically coupled to a second set of electrically-conductive biased contacts of the second plurality, the first slot and the second slot being positioned such that the first printed circuit board and the second circuit board are stacked in parallel in a spaced relationship; and
an extended housing that extends away from the main housing, the extended housing comprising:
a set of electrical connectors configured to be electrically coupled to a backup energy source, a third set of electrically-conductive biased contacts of the first plurality being electrically coupled to the set of electrical connectors.

2. The connector assembly of claim 1, wherein the set of electrical connectors is electrically coupled to the third set of electrically-conductive biased contacts of the first plurality by an electrically-conductive path contained within the extended housing and the main housing.

3. The connector assembly of claim 1, wherein the connector assembly is constructed from plastic, and each biased contact of the first plurality of electrically-conductive biased contacts is over-molded in the plastic.

4. The connector assembly of claim 3, wherein each biased contact of the second plurality of electrically-conductive biased contacts is over-molded in the plastic.

5. The connector assembly of claim 1, wherein a fourth set of electrically-conductive biased contacts of the second plurality is electrically coupled to the set of electrical connectors.

6. The connector assembly of claim 1, wherein the first plurality of electrically-conductive biased contacts is disposed on at least one side of the first slot, and the second plurality of electrically-conductive biased contacts is disposed on at least one side of the second slot.

7. The connector assembly of claim 1, wherein the first slot is an edge board connector.

8. The connector assembly of claim 7, wherein the edge board connector is a first edge board connector, and wherein the second slot is a second edge board connector.

9. The connector assembly of claim 1, wherein the first printed circuit board and the second printed circuit board implement at least some portion of a memory sub-system, wherein the first printed circuit board comprises a separate connector that is configured to electrically couple to and receive main power from a host system, wherein the separate connector is separate from the conductive surface contacts disposed on the first edge, and wherein the first printed circuit board is configured to receive backup power from the third set of electrically-conductive biased contacts by way of the third set of electrically-conductive biased contacts of the first plurality.

10. The connector assembly of claim 1, wherein each biased contact of the first plurality of electrically-conductive biased contacts is part of a horseshoe-shaped element.

11. The connector assembly of claim 1, wherein each biased contact of the second plurality of electrically-conductive biased contacts is part of a horseshoe-shaped element.

12. The connector assembly of claim 1, wherein the set of electrical connectors are lugs configured to electrically connect to a positive terminal of the backup energy source and a negative terminal of the backup energy source.

13. The connector assembly of claim 1, comprising:
a set of pins accessibly outside of the connector assembly, the set of pins is configured to provide debug access to at least one of the first printed circuit board or the second printed circuit board.

14. The connector assembly of claim 1, wherein the first printed circuit board is manufactured using a surface-mount technology (SMT) process.

15. The connector assembly of claim 1, wherein the first slot and the second slot are positioned parallel and adjacent to each other in a housing of the connector assembly.

16. The connector assembly of claim 1, wherein the backup energy source comprises at least one of a set of batteries or a set of capacitors.

17. A memory sub-system comprising:
a first printed circuit board that comprises:
a memory sub-system controller;
power circuitry; and
a host connector configured to electrically couple the memory sub-system to a host system;
a second printed circuit board that comprises a set of memory devices;
a backup energy source; and
a connector assembly configured to electrically couple together the first printed circuit board and the second printed circuit board, to electrically couple the first printed circuit board to the backup energy source, the connector assembly comprising:
a first slot that receives a first edge of the first printed circuit board, the first edge being inserted into the first slot, the first slot comprising a first plurality of electrically-conductive biased contacts configured to electrically couple with corresponding electrically-conductive surface contacts disposed on the first edge; and
a second slot that receives a second edge of the second printed circuit board, the second edge being inserted into the second slot, the second slot comprising a second plurality of electrically-conductive biased contacts configured to electrically couple with corresponding electrically-conductive surface contacts disposed on the second edge, a first set of electrically-conductive biased contacts of the first plurality being electrically coupled to a second set of electrically-conductive biased contacts of the second plurality, the first slot and the second slot being positioned such that the first printed circuit board and the second circuit board are stacked in parallel in a spaced relationship; and
a set of electrical connectors configured to be electrically coupled to the backup energy source, a third set of electrically-conductive biased contacts of the first plurality being electrically coupled to the set of electrical connectors.

18. The memory sub-system of claim 17, wherein the connector assembly comprises a main housing and an extended housing that extends away from the main housing, wherein the main housing comprises the first slot and the second slot, wherein the extended housing comprises the set of electrical connectors, and wherein the set of electrical connectors is electrically coupled to the third set of electrically-conductive biased contacts of the first plurality by an electrically-conductive path contained within the extended housing and the main housing.

19. The memory sub-system of claim 17, wherein the first slot is a first edge board connector, and wherein the second slot is a second edge board connector.

20. The memory sub-system of claim 17, wherein the first printed circuit board is configured to receive main power from the host system, and wherein the first printed circuit board is configured to receive backup power from the backup energy source by way of the third set of electrically-conductive biased contacts of the first plurality.
